(19) United States
(12) Patent Application Publication
(10) Pub. No.: US 2005/0169336 A1
(43) Pub. Date: Aug. 4, 2005

(54) Vertical-cavity surface-emitting semiconductor laser

(75) Inventors: Ryoji Ishii, Kanagawa (JP); Hideo Nakayama, Kanagawa (JP); Yasuaki Kuwata, Kanagawa (JP)

Correspondence Address: OLIFF & BERRIDGE, PLC, P.O. BOX 19928, ALEXANDRIA, VA, 22320, US

(73) Assignee: FUJI XEROX CO., LTD., Tokyo (JP)

(21) Appl. No.: 10/899,046

(22) Filed: Jul. 27, 2004

(30) Foreign Application Priority Data
Feb. 4, 2004 (JP) 2004-027877

(51) Int. Cl. H01S 5/00

(52) U.S. Cl. 372/50

(57) ABSTRACT

A surface-emitting semiconductor laser includes comprising a substrate, a first mesa that is formed on the substrate and includes at least one mesa capable of emitting laser light, and a second mesa that is formed on the substrate and includes at least one mesa restraining emission of laser light.

### BACKGROUND OF THE INVENTION

1. Field of the Invention

The present invention relates to a vertical-cavity surface-emitting semiconductor laser (VCSEL), and more particularly, to improvements in the electrostatic damage threshold voltage thereof.

2. Description of the Related Art

VCSEL has technical advantages that a threshold current is small, an optical spot of a circular shape can be easily obtained, and an evaluation at a wafer state and two dimensional array of the light source can be achieved. VCSEL has been expected to be used as a light source for optical communication devices and electronic devices.

VCSEL may happen to be exposed to a high voltage such as static electricity at the time of mounting on a printed-circuit board or the like as in the case of other semiconductor devices. If electrostatic discharge (hereinafter simply referred to as ESD) occurs in the device, spike current instantaneously will flow therein and may break down or degrade the device. The device is thus defective and is no longer capable of operating normally. Some proposals that cope with the above-mentioned problem have been reported.

For example, Japanese Laid-Open Patent Application Publication No 5-243666 proposes a semiconductor laser with an improved damage threshold voltage. The plane direction of a GaAs substrate of the semiconductor laser is inclined by an angle of 5° towards (01-1) from (100). This modifies the optical waveguide mode at an optical output lower than the optical output that causes an edge damage, and thus increases the magnitude of current at which an edge damage occurs.

Japanese Laid-Open Patent Application Publication No. 11-112026 proposes to provide a protection device separate from the light-emitting device. This proposal is based on such as consideration that the light-emitting semiconductor devices have small forward and reverse damage threshold voltages, and particularly, the GaN compound semiconductor has a reverse damage threshold voltage as small as 50 V and a forward damage threshold voltage as small as 150 V. The protection device may be a Zener diode or a transistor. The protection device short-circuits a reverse voltage applied across the light-emitting device or a forward voltage that exceeds the operating voltage.

The following paper reports the reliability of selective oxidization type VCSEL, and describes the relation between the ESD-induced damage voltage and the aperture defined by oxidizing. In this report, ESD-induced damage is tested using the human body model prescribed in the MIL standard, and a sample having an oxide aperture diameter of 5 to 20 μm is used. A pulse voltage is applied across VCSEL in the forward and backward directions, and a situation in which the optical output changes by −2 dB is defined as damage or failure. FIG. 9 of the paper shows the results of the ESD-induced damage test. The reported results suggest that ESD-induced damage is a function of the diameter of the oxide aperture or area, and the ESD-induced damage threshold voltage becomes higher as the size of the oxide aperture becomes larger.

The method of inclining the plane direction of the substrate disclosed in Japanese Laid-Open Patent Application Publication No 5-243666 is directed specifically to measures for electrostatic damage inherent in the edge-emitting laser, and may not be effective to VCSEL. The protection device disclosed in Japanese Laid-Open Patent Application Publication No. 11-112026 does not improve the electrostatic damage threshold voltage within the light-emitting device. Thus, the laser apparatus needs an increased number of components and is thus expensive.

The above-mentioned paper suggests that the ESD-induced damage threshold voltage becomes higher in proportion to the diameter of the oxide aperture. However, desired fundamental characteristics of laser will not be obtained by merely increasing the oxide aperture size. Particularly, the single-mode VCSEL tends to have a reduced size of the oxide aperture, which really reduces the ESD-induced damage threshold voltage.

### SUMMARY OF THE INVENTION

The present invention has been made in view of the above circumstances and provides a surface-emitting semiconductor laser comprising: a substrate; a first mesa that is formed on the substrate and includes at least one mesa capable of emitting laser light; and a second mesa that is formed on the substrate and includes at least one mesa restraining emission of laser light.

### BRIEF DESCRIPTION OF THE DRAWINGS

Preferred embodiments of the present invention will be described in detail based on the following figures, wherein:

FIG. 1A is a schematic plan view of a VCSEL according to a first embodiment of the present invention;

FIG. 1B is a sectional view taken along a line X-X shown in FIG. 1A;

FIG. 2 is a graph showing a relation between an oxide aperture area and a breakdown voltage;

FIG. 3A is a schematic plan view of a VCSEL according to a second embodiment of the present invention;

FIG. 3B is a sectional view taken along a line X-X shown in FIG. 3A;

FIGS. 4A and 4B are schematic plan views of VCSELs according to a third embodiment of the present invention;

FIGS. 5A and 5B are schematic plan views of VCSELs according to a fourth embodiment of the present invention; and

FIGS. 6A through 6D show a method of fabricating the VCSEL according to the first embodiment of the present invention.

### DESCRIPTION OF THE PREFERRED EMBODIMENTS

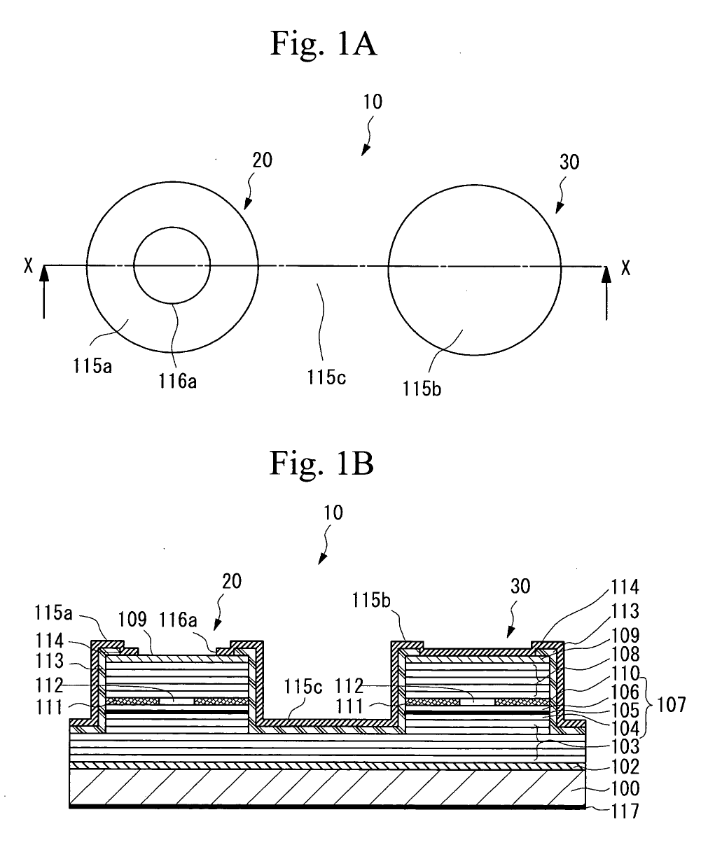

FIG. 1A is a schematic plan view of a VCSEL according to a first embodiment of the present invention, and FIG. 1B is a sectional view taken along a line X-X shown in FIG. 1A. A VCSEL 10 according to the present embodiment has a mesa (first mesa) 20 from which laser light is emitted, and another mesa (second mesa) 30 from which no laser light is emitted. The first and second mesas 20 and 30 are formed on a single substrate. The mesa 30 functions as a dummy that does not emit laser light at all, and substantially increases the area of the oxide aperture of the VCSEL 10. It is therefore possible to improve the ESD-induced damage threshold voltage. The area of the oxide aperture of laser light emitted from the mesa 20 can be reduced to, for example, an area for the single mode, so that the fundamental laser characteristics cannot be degraded at all.

As shown in FIG. 1B, the VCSEL 10 has an n-type GaAs substrate 100, on which provided are an n-type buffer layer 102, an n-type lower DBR (Distributed Bragg Reflector) mirror layer 103, an active region 107, a p-type upper DBR mirror layer 108, and a p-type contact layer 109, these layers being laminated in that order. The active region 107 is composed of an undoped lower spacer layer 104, an undoped quantum well active layer 105, and an undoped upper spacer layer 106. The mesas 20 and 30 can be simultaneously formed by anisotropically etching the semiconductor laminate on the substrate. The mesas 20 and 30 have cylindrical shapes and have an identical size (diameter).

The mesas 20 and 30 have p-type AlAs layers 110 as the lowermost layers of p-type upper DBR mirror. The AlAs layers 110 have oxidized regions 111 that have been oxidized from the side surfaces of the mesas 20 and 30, and circularly shaped oxide apertures (electrically conductive regions) 112 surrounded by the oxidized regions. The AlAs layers 110 function to confine light and current by the oxidized regions 111.

The sidewalls and the upper surfaces of the mesas 20 and 30 are covered with an interlayer insulating film 113. The interlayer insulating film 113 have contact holes 114 through which contact layers 109, which are parts of the mesas 20 and 30, are exposed. In the mesa 20, a p-side electrode layer 115a is formed on the interlayer insulating film 113, and makes an ohmic contact with the contact layer 109 via a contact hole 114. A laser emission aperture 116a via which laser light is emitted is formed in the center of the p-side electrode layer 115a.

In the mesa 30, a p-side electrode layer 115b is formed on the interlayer insulating film 113, and makes an ohmic contact with the contact layer 109 via another contact hole 114. It is to be noted that no laser emission aperture is formed in the p-side electrode layer 115b. This is different from the mesa 20. Current is injected into the mesa 30 and laser oscillation takes place. However, laser light is not emitted via the top of the mesa 30. The p-side electrode layer 115b is connected to the p-side electrode layer 115a by a metal layer 115c on the mesa bottom. The metal layer 115c may be simultaneously formed when the p-side electrodes 115a and 115b are formed by patterning, as will be described later. The p-side electrode layers 115a and 115b are electrically connected to an electrode pad (not shown). An n-side electrode 117, which is common to the mesas 20 and 30, is provided on the back surface of the substrate 100.

The lower DBR mirror layer 103 is the laminate of n-type Al_{0.9}Ga_{0.1}As layers and n-type Al_{0.3}Ga_{0.7}As layers, which are alternately laminated one by one. Each of the layers that form the laminate of the lower DBR layer 103 has a thickness equal to λ/4nᵣ wherein λ is the oscillation wavelength, and nᵣ is the optical refractive index in the medium. Two types of layers having different Al composition ratios are alternatively laminated to 40.5 periods. The carrier concentration after doping with silicon that is an n-type impurity is 3×10¹⁸cm⁻³.

The lower spacer layer 104 that underlies the active region 107 may be an undoped Al_{0.6}Ga_{0.4}As layer. The quantum well active layer 105 includes an undoped Al_{0.11}Ga_{0.89}As quantum well layer and an undoped Al_{0.3}Ga_{0.7}As barrier layer. The upper spacer layer 106 may be an undoped Al_{0.6}Ga_{0.4}As layer.

The upper DBR mirror layer 108 is a laminate of p-type Al_{0.9}Ga_{0.1}As layers and p-type Al_{0.3}Ga_{0.7}As layers, which are alternately laminated one by one. Each of the layers that form the laminate of the lower DBR layer 108 has a thickness equal to λ/4nᵣ wherein λ is the oscillation wavelength, and nᵣ is the optical refractive index in the medium. Two types of layers having different Al composition ratios are alternatively laminated to 30 periods. The carrier concentration after doping with carbon that is a p-type impurity is 3×10¹⁸cm⁻³. The p-type contact layer 109 may be a GaAs layer, which is 20 nm thick, and has a carbon concentration of 1×10²⁰ cm⁻³. The p-side electrodes 115a and 115b maybe a laminate film of Ti/Au.

When the VCSEL 10 is driven, a forward voltage is applied between the p-side electrodes 115a and 115b and the n-side electrode 117, and current is injected into the mesas 20 and 30. Laser oscillation having a wavelength dependent on the thickness of the active region 107 of the mesa 20 occurs, and similarly laser oscillation having a wavelength dependent on the thickness of the active region 107 of the mesa 30 occurs. In the mesa 20, laser light is emitted via the laser emission aperture 116a of the p-side electrode layer 115a. In contrast, laser light oscillated in the mesa 30 is shut out by the p-side electrode layer 115b, so that emission of laser light can be restrained. In other words, the mesa 30 has a current path for the current injected via the electrodes, but does not have any function of laser emission.

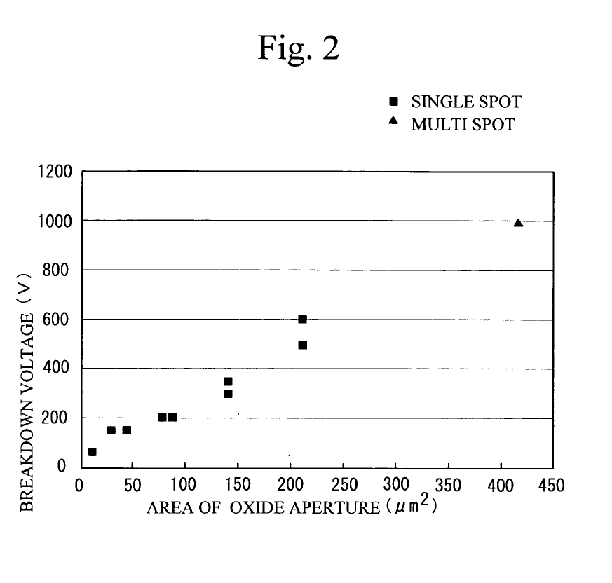

FIG. 2 is a graph showing a relation between the breakdown voltage and the oxide aperture area. The horizontal axis of the graph denotes the oxide aperture area (μm²), and the vertical axis thereof denotes the breakdown voltage (V). The experimental results of FIG. 2 show the breakdown voltage (indicated by square dots) as a function of the oxide aperture size in the single-spot structure (single mesa), and the breakdown voltage (indicated by triangular dots) as that in the multi-spot structure (multiple mesas).

As will be apparent from the aforementioned paper and the experimental results of FIG. 2, the area of the oxide aperture is proportional to the breakdown voltage, which can be improved as the area of the oxide aperture increases. In the first embodiment of the invention, the mesas 20 and 30 have outer shapes of an equal size. Thus, the mesas 20 and 30 have the oxide apertures having the same area under the same oxidizing process. Thus, the VCSEL of the present invention has an oxide aperture area equal to twice the oxide aperture area obtained in the single-mesa structure, and has improved breakdown voltage. For example, when the single mesa structure having only the mesa 20 has an oxide aperture diameter of 8 μm, the oxide aperture area is approximately equal to 50 μm², and a breakdown voltage of about 180 V is available. In contrast, the VCSEL of the present invention with the mesa 30 in addition to the mesa 20 has an oxide aperture area of about 100 μm², and has an improved breakdown voltage up to about 200 V.

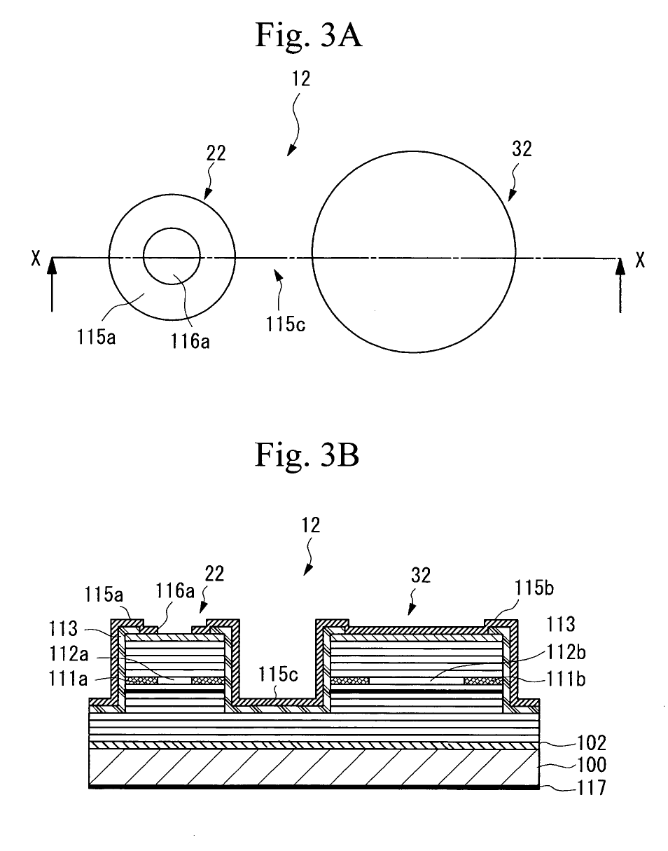

A description will now be given of a second embodiment of the present invention with reference to FIGS. 3A and 3B. A VCSEL 12 according to the second embodiment has a mesa 22 capable of emitting laser light of a single mode, and a mesa 32 having a larger size than that of the mesa 22 in order to improve the damage threshold voltage. The other structures of the VCSEL 12 are the same as corresponding those of the VCSEL 10. The p-side electrode layer 115a provided on the top of the mesa 22 has the laser emission aperture 116a, while the p-side electrode layer 115b provided on the top of the mesa 32 does not have any laser emission aperture.

The mesas 22 and 32 are formed on the substrate by the single process, and oxidizing is carried out under the same condition. Thus, the oxidizing distance from the sidewall of the mesa 22 is equal to that from the sidewall of the mesa 32. An oxide aperture 112a of the mesa 22 has a diameter D1−S1 where D1 is the diameter of the mesa 22 (before the interlayer insulating film is formed), and S1 is the oxidizing distance. An oxide aperture 112b of the mesa 32 has a diameter D2−S1 where D2 is the diameter of the mesa 32. The above parameters satisfy the following condition:
(D1−S1)<(D2−S1).

The oxide aperture diameter of the mesa 22 is reduced to a size enough to cause single-mode oscillation (for example, 5 μm), while the oxide aperture diameter of the mesa 32 is set larger than that of the mesa 32 in order to improve the breakdown voltage.

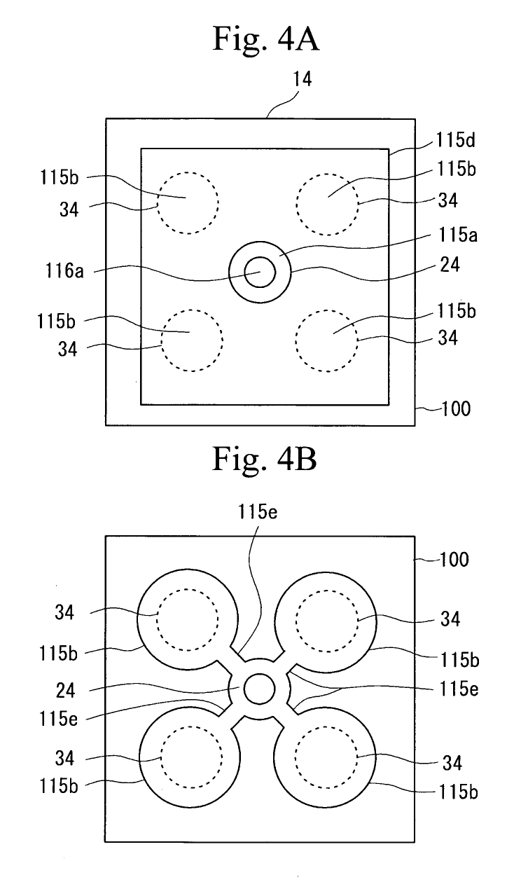

FIG. 4A is a plan view of a VCSEL according to a third embodiment of the present invention. A VCSEL 14 of the present embodiment has a mesa 24 and four mesas 34. The mesa 24 is located in the center of a substrate 100 and has the function of emitting laser light. The four mesas 34, which are shown by broken lines, are arranged in the vicinity of the mesa 24 so as to surround the mesa 24. The mesas 24 and 34 have a cylindrical shape of the same size. The top of the mesa 24 is covered with the p-side metal layer 115a, which has the laser emission aperture 116a. In contrast, the mesas 34 function as current paths, but do not have any laser emission apertures, so that no laser can be emitted from the mesas 34.

Preferably, the four mesas 34 are arranged on imaginary diagonal lines that pass through the center of the mesa 24, and are positioned at the same distance from the center of the mesa 24. In order to downsize the VCSEL, it is desirable to arrange the mesas 34 as close to the mesa 24 as possible. However, the influence of head developed by the mesas 34 should be considered. Taking the influence of heat into account, the mesas 34 are an equal distance away from the mesa 24. The p-side electrode layer 115a of the mesa 24 and the p-side electrodes 115b of the mesas 34 are connected together by a metal layer pattern 115d formed on the whole surface of the substrate 100.

FIG. 4B shows another interconnection pattern of the p-side electrode layers. The p-side electrodes 115b have a circular shape that corresponds to the outer shapes of the mesas 34, and are connected to the p-side electrode layer 115a by a joining pattern 115e.

According to the third embodiment, the use of the mesas 34 increases the total oxide aperture area to five times the oxide aperture area of the single-mesa structure with the mesa 24 only, and further improves the breakdown voltage. The third embodiment has a single mesa capable of emitting laser light. However, the third embodiment is limited to the above, and includes a multi-spot structure with mesas each capable of emitting laser light. The mesa 34 can be arranged around those mesas.

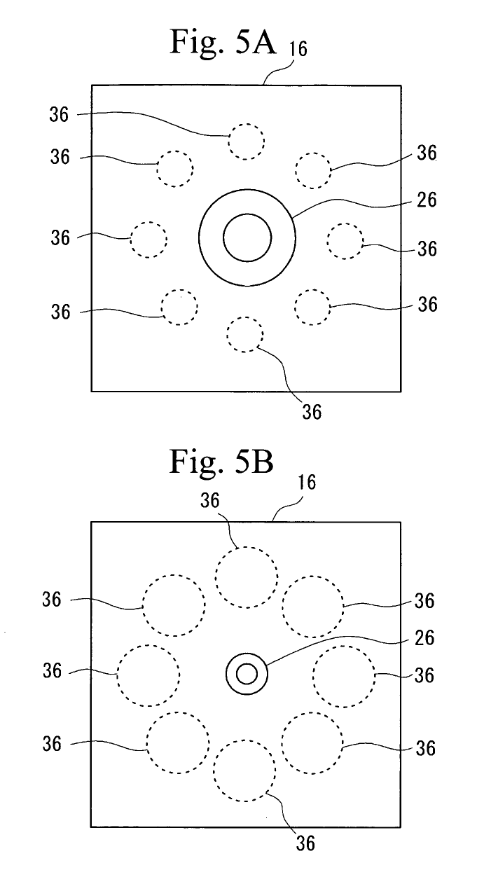

FIG. 5A is a schematic plan view of a VCSEL according to a fourth embodiment of the present invention, and FIG. 5B is a schematic plan view of a variation of the VCSEL shown in FIG. 5A. A VCSEL 16 according to the fourth embodiment has a mesa 26, and eight mesas 36 (shown by broken lines) radially arranged around the mesa 26. The eight mesas 36 do not emit laser light. The mesa 26 shown in FIG. 5A has an outer shape having a size larger than the size of the outer shapes of the eight mesas 36. In contrast, the mesa 26 shown in FIG. 5B has an outer shape having a size smaller than the size of the outer shapes of the eight mesas 36. The mesas 36 are symmetrically arranged with respect to the mesa 26.

As described above, at least one dummy mesa that functions as the current path only is additionally arranged, so that a desired oxide aperture area can be ensured and designed VCSEL breakdown voltage can be obtained. The dummy mesa or mesas may have the same size as the regular mesa capable of emitting laser light or may have a size different from that of the regular mesa. The regular and dummy mesas may not apply only to cylindrical shape and may have a rectangular column shape.

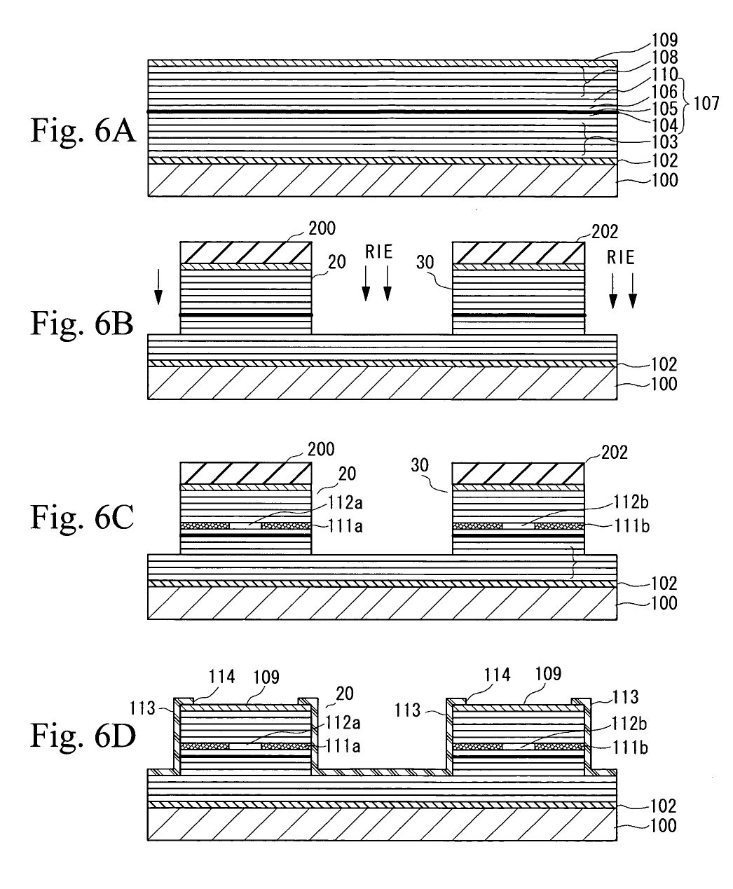

A description will now be given, with reference to FIGS. 6A through 6D, of a method of fabricating the VCSEL shown in FIGS. 1A and 1B. Referring to FIG. 6A, multiple semiconductor lasers are laminated on the substrate 100 by MOCVD (Metal Organic Chemical Vapor Deposition). That is, on the n-type GaAs substrate 100, provided are the n-type buffer layer 102, the n-type lower DBR mirror layer 103, the active region composed of the undoped lower spacer layer 104, the undoped quantum well active layer 105 and the undoped upper spacer layer 106, the AlAs layer (current confining layer) 110, the p-type upper DBR mirror 108, and the p-type contact layer 109 in that order.

Next, as shown in FIG. 6B, mask patterns 200 and 202 are formed on the semiconductor laminate by using the photolithographic process. The mask patterns 200 and 202 may be SiO₂ or resist. The mask pattern 200 has a circular shape that corresponds to the outer shape of the mesa 20. The mask pattern 202 has a circular pattern that corresponds to the outer shape of the mesa 30.

Using the mask patterns 200 and 202, the semiconductor laminate is etched by RIE (Reactive Ion Etching). Etching is performed until a part of the lower mirror layer 103 is exposed, so that the mesas 20 and 30 can be defined.

Then, as shown in FIG. 6C, the substrate 100 is exposed to a moisture atmosphere at 350° C. for 30 minutes in which nitrogen (flow rate: 2 liters per minute) is used as a carrier gas. The AlAs layer 110 is oxidized much faster than the Al_{0.8}Ga_{0.2}As layer and Al_{0.1}Ga_{0.9}As layer that form the upper mirror layer. Thus, oxidizing of the AlAs layer 110 starts from the side surfaces of the mesas, and the oxide apertures 112a and 112b respectively surrounded by the oxidized regions 111a and 111b that reflect the outer shapes of the mesas can be defined. The oxide apertures 112a and 112b thus formed are the current confining layers. The oxidized regions 111a and 111b have reduced conductivity and thus confine current. Simultaneously, the oxide apertures 112a and 112b have an optical refractive index that is approximately half (˜1.6) the refractive indexes of the peripheral semiconductor layers, and thus function as light confining regions. The oxide apertures (non-oxidized regions) 112a and 112b are current-injected regions.

Thereafter, as shown in FIG. 6B, the mask patterns 200 and 202 are removed, and the surface of the substrate including the exposed side surfaces of the mesas is coated with the interlayer insulating film 113. Then, the contact holes 114 are formed in the interlayer insulating film 113 on the tops of the mesas 20 and 30. Subsequently, the p-side electrode is formed on the substrate, and is connected to the contact layers 109 via the contact holes 114 on the tops of the mesas 20 and 30.

Then, as shown in FIG. 1B, the p-side electrode layer is patterned. On the top of the mesa 20, the laser emission aperture 116a is formed in the p-side electrode layer 115a. In contrast, no laser emission aperture is formed in the p-side electrode layer 115b on the top of the mesa 30. Further, the pattern 115c that connects the p-side electrode layer 115a and the p-side electrode layer 115b is simultaneously formed. Finally, the n-side electrode 117 is formed on the back surface of the substrate 100.

The present invention is not limited to the specifically disclosed embodiments, and other embodiments, variations and modifications may be made without departing from the scope of the present invention. For example, the above-mentioned embodiments employ the current confining layers of AlAs. However, the present invention is not limited to the above but may use a current confining layer of AlGaAs. The above-mentioned embodiments GaAs compound semiconductor lasers, but the present invention includes other types of semiconductor laser such as GaN semiconductor laser and GaIn semiconductor laser.

The VCSEL of the present invention may be used as light sources of optical communication devices using optical fiber cables, an optical communication system using these devices, an electronic apparatus that optically reads and write information from and into a recording medium, and copying machines.

The entire disclosure of Japanese Patent Application No. 2004-027877 filed on Feb. 4, 2004 including specification, claims, drawings and abstract is incorporated herein by reference in its entirety.

1. A surface-emitting semiconductor laser comprising:
a substrate;
a first mesa that is formed on the substrate and includes at least one mesa capable of emitting laser light; and
a second mesa that is formed on the substrate and includes at least one mesa restraining emission of laser light.

2. The surface-emitting semiconductor laser as claimed in claim 1, wherein:
the first and second mesas include metal layers on respective tops;
the metal layer of the first mesa has an aperture through which laser light is emitted; and
the metal layer of the second mesa shuts out laser light.

3. The surface-emitting semiconductor laser as claimed in claim 2, wherein the metal layers of the first and second mesas are metal electrodes via which currents are injected to the first and second mesas.

4. The surface-emitting semiconductor laser as claimed in claim 2, wherein the metal layers of the first and second mesas are electrically connected.

5. The surface-emitting semiconductor laser as claimed in claim 1, wherein:
the first and second mesas include current confining layers formed therein;
the current confining layers include oxidized regions and oxide apertures surrounded by the oxidized regions; and
the oxide aperture of the second mesa has a size larger than that of the oxide aperture of the first mesa.

6. The surface-emitting semiconductor laser as claimed in claim 5, wherein the oxide aperture of the second mesa has an area larger than that of the oxide aperture of the first mesa.

7. The surface-emitting semiconductor laser as claimed in claim 6, wherein the second mesa includes a plurality of mesas, and the total area of oxide apertures of the plurality of mesas is larger than the area of the oxide aperture of the first mesa.

8. The surface-emitting semiconductor laser as claimed in claim 1, wherein the second mesa includes a plurality of mesas, which are arranged around the first mesa and are located at an approximately equal distance from the first mesa.

9. The surface-emitting semiconductor laser as claimed in claim 8, wherein the plurality of mesas are radially arranged from a center of the first mesa.

10. The surface-emitting semiconductor laser as claimed in claim 8, wherein the plurality of mesas are symmetrically arranged with respect to the center of the first mesa.

11. The surface-emitting semiconductor laser as claimed in claim 1, wherein the first mesa emits laser light of a single mode.

12. The surface-emitting semiconductor laser as claimed in claim 1, wherein the first mesa includes a plurality of mesas, which are simultaneously driven to emit laser lights of multi-spots.

13. The surface-emitting semiconductor laser as claimed in claim 1, wherein:
the first and second mesas have a vertical-cavity resonator structure that includes a lower semiconductor mirror layer and an upper semiconductor mirror layer; and
a current confining layer and an active region are interposed between the lower and upper semiconductor mirror layers.

14. The surface-emitting semiconductor laser as claimed in claim 1, wherein the first and second mesas are simultaneously formed by anisotropic etching on the substrate.

15. The surface-emitting semiconductor laser as claimed in claim 13, wherein the lower and upper semiconductor mirror layers are AlGaAs layers, and the current confining layers are AlAs or AlGaAs layers.
